(19) United States
(12) Patent Application Publication
(10) Pub. No.: US 2025/0194371 A1
(43) Pub. Date: Jun. 12, 2025

(54) HYBRID ACTIVE-PASSIVE MATRIX DEVICES FOR DISPLAYS, LIGHTING AND SIGNALING

(71) Applicant: Mattrix Technologies, Inc., Gainesville, FL (US)

(72) Inventors: Bo Liu, Gainesville, FL (US); Xiao Chen, Gainesville, FL (US); Maxime Gregory Lemaitre, Gainesville, FL (US); Svetlana Viktorovna Vasilyeva, Gainesville, FL (US)

(21) Appl. No.: 18/972,355

(22) Filed: Dec. 6, 2024

Related U.S. Application Data
(60) Provisional application No. 63/606,978, filed on Dec. 6, 2023.

(51) Int. Cl. H10K 59/35; H10K 50/30; H10K 59/82

(52) U.S. Cl. CPC H10K 59/353; H10K 59/82; H10K 50/30

(57) ABSTRACT

Various examples are provided related to hybrid active-passive matrix devices. In one example, an active matrix device includes an array of geometrically shaped VOLET pixels arranged to form an emissive display, where each pixel is visibly discernable to a user; and bus lines routed along edges of the geometrically shaped VOLET pixels. The bus lines include a Vdata line, a Vscan line, and a VDD line. The active matrix device can include a first region formed by the array of geometrically shaped VOLET pixels and a second region including a display panel including pixels that are visibly undiscernible to the user. The active matrix device can include a third region including one or more passive VOLET pixels, which can be larger than the geometrically shaped VOLET pixels.

### CROSS REFERENCE TO RELATED APPLICATIONS

This application claims priority to, and the benefit of, U.S. provisional application entitled “Hybrid Active-Passive Matrix Devices with High Fill Factor, Arbitrary Size and Shape Vertical Light Emitting Transistor Pixels for Displays, Lighting and Signaling” having Ser. No. 63/606,978, filed Dec. 6, 2023, which is hereby incorporated by reference in its entirety.

### BACKGROUND

Automotive vehicles on the road are fitted with multiple sets of external lighting fixtures, serving crucial functions related to safety, signaling, and visibility. Presently, the automotive industry has become one of the most active sectors to implement innovative display and lighting technologies for interior and exterior use. Automotive interior displays have already become the crucial car components that provide drivers and passengers with essential information. The fast-evolving sophistication of modern display technologies is pushing automotive OEMs to reimagine the design and drastically broaden functions/controls of the car interior.

### SUMMARY

Aspects of the present disclosure are related to hybrid active-passive matrix devices, their uses and applications. In one aspect, among others, an active matrix device comprises an array of geometrically shaped VOLET pixels arranged to form an emissive display, where each pixel is visibly discernable to a user; and bus lines comprising a Vdata line, a Vscan line, and a VDD line routed along edges of the geometrically shaped VOLET pixels. In one or more aspects, the geometrically shaped VOLET pixels can comprise triangular pixels. The Vdata line, Vscan line, and VDD line can be routed along different edges of the triangular pixels. The geometrically shaped VOLET pixels can have a linear dimension in its length, width, height or center to center distance in either X or Y axis in a range between 0.5 millimeters and 25 millimeters.

In various aspects, the active matrix device can comprise a first region formed by the array of geometrically shaped VOLET pixels; and a second region comprising a display panel including pixels that are visibly undiscernible to the user. The first and second regions can share a portion of the bus lines. Both the first region and the second region can be fabricated on a common substrate through a series of common processing steps. The substrate can be flexible. The substrate can comprise a polyimide material. The pixels in the second region that are visibly undiscernible to the user can have a linear dimension in its length, width, height or center to center distance in either X or Y axis in a range between 25 micrometers and 1.5 millimeters; and the geometrically shaped VOLET pixels can have a linear dimension in its length, width, height or center to center distance in either X or Y axis greater than 1.5 millimeters. Individual pixels in the second region that are visibly undiscernible to the user can comprise two or more individually controllable sub-pixels with different color emission thereby allowing each pixel to represent a plurality of colors perceivable by human.

In some aspects, the active matrix device can comprise a third region comprising one or more passively addressed or individual bus line direct driven VOLET pixels or OLED light emitting segments that are larger than the geometrically shaped VOLET pixels. The first region, the second region, and the third region can be fabricated on a common substrate through a series of common processing steps. The substrate can be flexible. The substrate can comprise a polyimide material. The one or more passively addressed or individual bus line direct driven VOLET pixels or OLED light emitting segments in the third region can have a linear dimension in its length, width, height and/or center to center distance in either X or Y axis in a range between 10 millimeters and 500 millimeters.

In one or more aspects, each geometrically shaped VOLET pixel can comprise a switching thin film transistor (sw-TFT) disposed along an edge of that geometrically shaped VOLET pixel. The sw-TFT can be at least partially disposed below a non-emitting area of the geometrically shaped VOLET pixel. The bus lines can be routed along non-emitting areas between the geometrically shaped VOLET pixels. The Vdata line can be routed along a first side of a geometrically shaped VOLET pixel, the Vscan line can be routed along a second side of the geometrically shaped VOLET pixel, and the VDD line can be routed along a third side of the geometrically shaped VOLET pixel. The bus lines can comprise first and second Vscan lines routed in parallel, positioned side-by-side along edges of adjacent geometrically shaped VOLET pixels. The first Vscan line can be coupled to geometrically shaped VOLET pixels on a first side of the first and second Vscan lines and the second Vscan line can be coupled to geometrically shaped VOLET pixels on a second side of the first and second Vscan lines. The Vdata line can be routed along edges of adjacent geometrically shaped VOLET pixels, and coupled to the adjacent geometrically shaped VOLET pixels, which are coupled by different Vscan lines, on both a first side and a second side of the Vdata line.

In various aspects, the geometrically shaped VOLET pixels can have a fill factor of greater than 80%, a fill factor of greater than 87%, or a fill factor of greater than 90%. Each of the geometrically shaped VOLET pixels can be separated into a plurality of subpixels. The plurality of subpixels can comprise triangular subpixels. The plurality of subpixels can comprise hexagonal subpixels. Each subpixel can comprise a switching thin film transistor (sw-TFT) disposed along an edge of that subpixel. The sw-TFT can be at least partially disposed below a non-emitting area of the subpixel.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims. In addition, all optional and preferred features and modifications of the described embodiments are usable in all aspects of the disclosure taught herein. Furthermore, the individual features of the dependent claims, as well as all optional and preferred features and modifications of the described embodiments are combinable and interchangeable with one another.

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1 is a schematic diagram illustrating an example of an active-matrix organic light-emitting diode (AMOLED) display circuit connection scheme, in accordance with various embodiments of the present disclosure.

FIG. 2 is a schematic diagram illustrating an example of a two transistor/one capacitor (2T1C) pixel circuit, in accordance with various embodiments of the present disclosure.

FIG. 3 illustrates an example of a vertical organic light-emitting transistor (VOLET) with carbon nanotube (CNT) network source electrode transmittance spectrum, in accordance with various embodiments of the present disclosure.

FIG. 4 is a schematic diagram illustrating an example of a VOLET and an a-Si switching thin film transistor (TFT) that simplify the AMOLED display pixel, in accordance with various embodiments of the present disclosure.

FIG. 5 illustrates an example of an active-matrix VOLET automotive external display with triangular pixels, in accordance with various embodiments of the present disclosure.

FIGS. 6A and 6B illustrate details of an example of the active-matrix VOLET circuit layout of FIG. 5, in accordance with various embodiments of the present disclosure.

FIG. 7 illustrates an example of the active matrix addressing scheme of a display panel with the full triangle pixels, in accordance with various embodiments of the present disclosure.

FIG. 8 is a cross-section view illustrating an example of an active matrix device, in accordance with various embodiments of the present disclosure.

FIG. 9 illustrates an example of a process flow that can be used to fabricate the active matrix device, in accordance with various embodiments of the present disclosure.

FIG. 10 illustrates an example of the visual effects of an 8×8 pixel array with different fill factors, in accordance with various embodiments of the present disclosure.

FIG. 11 illustrates an example of an example of an active-matrix VOLET automotive external display with split triangular pixels, in accordance with various embodiments of the present disclosure.

FIGS. 12A and 12B illustrate details of an example of the active-matrix VOLET circuit layout of FIG. 11, in accordance with various embodiments of the present disclosure.

FIG. 13 illustrates an example of the active matrix addressing scheme of a display panel with the split triangle pixels, in accordance with various embodiments of the present disclosure.

FIG. 14 illustrates an example of the visual effects of an 8×8 pixel array with different fill factors, in accordance with various embodiments of the present disclosure.

FIG. 15 illustrates another example of an example of an active-matrix VOLET automotive external display with split triangular pixels, in accordance with various embodiments of the present disclosure.

FIG. 16 illustrates an example of the visual effects of an 8×8 pixel array with different fill factors, in accordance with various embodiments of the present disclosure.

FIGS. 17A-17F illustrate examples of the visual effects of a 40×40 display panel with different fill factors, in accordance with various embodiments of the present disclosure.

FIG. 18 illustrates another example of an example of an active-matrix VOLET automotive external display with hexagon pixels (or subpixels), in accordance with various embodiments of the present disclosure.

FIGS. 19A and 19B illustrate details of an example of the active-matrix VOLET circuit layout of FIG. 18, in accordance with various embodiments of the present disclosure.

FIG. 20 illustrates an example of the active matrix addressing scheme of a display panel with the hexagon pixels (or subpixels), in accordance with various embodiments of the present disclosure.

FIG. 21 illustrates an example of the visual effects of an 8×8 pixel array with different fill factors, in accordance with various embodiments of the present disclosure.

FIGS. 22A and 22B illustrate examples of the visual effects of a 40×40 display panel with two different fill factors, in accordance with various embodiments of the present disclosure.

FIG. 23 illustrates an example of a display area comprising two regions composed of pixels of different sizes, in accordance with various embodiments of the present disclosure.

FIG. 24 is a schematic diagram illustrating an example of a display circuit connection scheme where certain Vgate lines are shared between rows of pixels in region A and region B, in accordance with various embodiments of the present disclosure.

FIGS. 25A and 25B are cross-sectional views illustrating examples of OLED stack formations for a hybrid active-matrix VOLET automotive external display with mixed pixels, in accordance with various embodiments of the present disclosure.

FIGS. 26A-26D illustrate examples of display designs and combinations of region A and region B, in accordance with various embodiments of the present disclosure.

FIG. 27 illustrates an example of a display area comprising three regions composed of pixels of different sizes, in accordance with various embodiments of the present disclosure.

FIGS. 28A and 28B are cross-sectional views illustrating examples of OLED stack formations for a monolithic hybrid active-passive-matrix VOLET/OLED automotive external light and display with mixed pixels and segments, in accordance with various embodiments of the present disclosure.

### DETAILED DESCRIPTION

Disclosed herein are various examples related to hybrid active-passive matrix devices which can be used in displays, lighting and signaling among other applications. Reference will now be made in detail to the description of the embodiments as illustrated in the drawings, wherein like reference numbers indicate like parts throughout the several views.

Future vehicles will incorporate larger size, higher resolution information displays seamlessly integrated into the car panel; flexible, rollable overhead displays; holographic heads-up displays; entertainment displays for the passengers; and intelligent ambient lighting. Mature liquid crystal display (LCD), more advanced Organic Light-Emitting Diode (OLED), and emerging micro-Light-Emitting Diode (microLED) and heads-up display (HUD) technologies presently compete for the expanding market of automotive interior displays.

The evolution of vehicle external lighting has been marked by significant technological advancements, aesthetic refinements, and functional diversification. Initially, incandescent light bulbs dominated automotive lighting, offering a standard level of brightness and the familiar warm glow. However, they were limited in longevity and efficiency. The advent of halogen lamps brought about improved brightness and longer lifespans, becoming a staple in automotive design for several decades. The transition to Light Emitting Diodes (LEDs) marked a revolutionary leap in the industry. LEDs offered superior longevity, lower energy consumption, and greater design flexibility, allowing for more intricate and brand-specific lighting signatures. OLEDs, Quantum OLEDs (QD-OLEDs), microLEDs technology are pushing the boundaries even further, providing even more precise lighting control and new possibilities for integration into the vehicle's bodywork.

Today, external vehicle lighting fixture functions extend well beyond basic operational necessity. Sophisticated lighting systems now serve as a platform for brand differentiation, embodying the essence of high-tech and luxury. Automakers use distinctive designs as a visual signature, instantly recognizable and often associated with the brand's image. Adaptive lighting/signaling systems that adjust to driving conditions not only improve safety but also reinforce the perception of a high-end, intelligent vehicle.

The future of vehicle communication blurs the lines between lighting and digital display, as signaling evolves to transmit increasingly complex information. This shift is propelled by the advent of autonomous vehicles, where the conventional driver-pedestrian exchange is non-existent. Now, it's imperative that pedestrians receive clear, intuitive signals from self-driving cars to navigate crossings safely. Lighting/signaling systems now play a pivotal role in automotive design, merging the capability to display rich information with the allure of high technology and luxury, thereby reinforcing brand identity and enhancing the experience on the road. With conventional control methods of manipulating individual bulbs or LEDs becoming inadequate, innovation calls for a new breed of device, one adept at meeting these evolving requirements.

Offering better display quality, faster response time, increased brightness and contrast, as well as scalable to high resolution and larger panel sizes, display devices using active matrix addressing scheme will be important for the next generation of automotive external lighting/signaling system. Each pixel in an active-matrix display panel, such as an AMOLED panel, contains a light emitting unit that lights up to form the display. Pixels are arranged in a matrix, where the refreshing of the screen is done in a row-by-row fashion. Each pixel in a row is refreshed simultaneously in a given time slot, after which the pixel is kept at a certain brightness level until the next cycle of refreshing, thus the name active matrix, in comparison with passive matrix where each pixel only maintains its brightness when it is addressed.

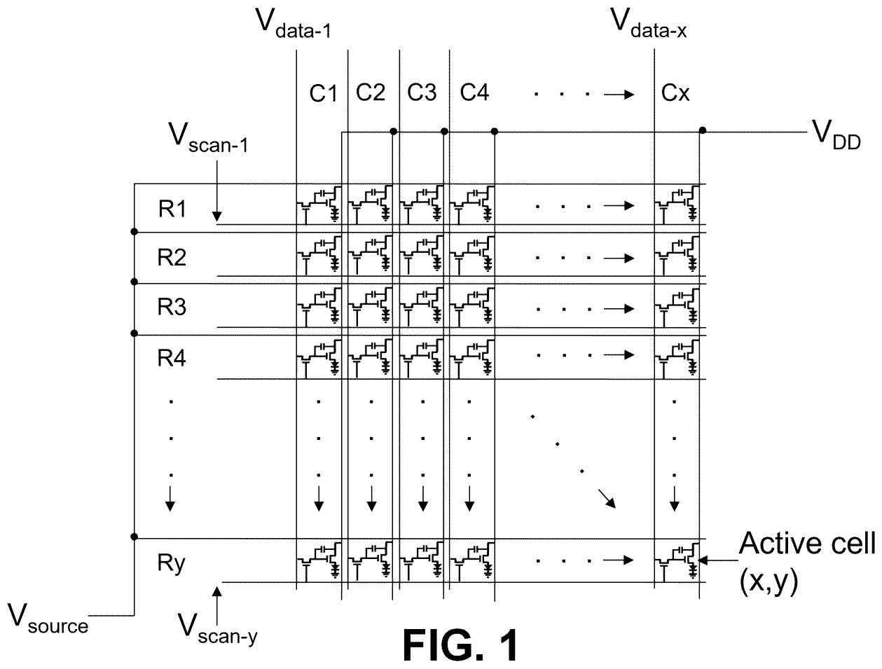

To maintain the brightness each pixel in an active-matrix display needs to memorize its brightness level, and the light emitting unit needs to be driven to light up. To achieve that each pixel contains a circuit, called the pixel circuit, to drive its light emitter. Pixel circuits are connected by bus lines that provide the signal and power to each circuit. The pixel circuits and bus lines form the backplane of the active-matrix display. FIG. 1 shows a schematic diagram illustrating an active-matrix OLED display circuit connection scheme.

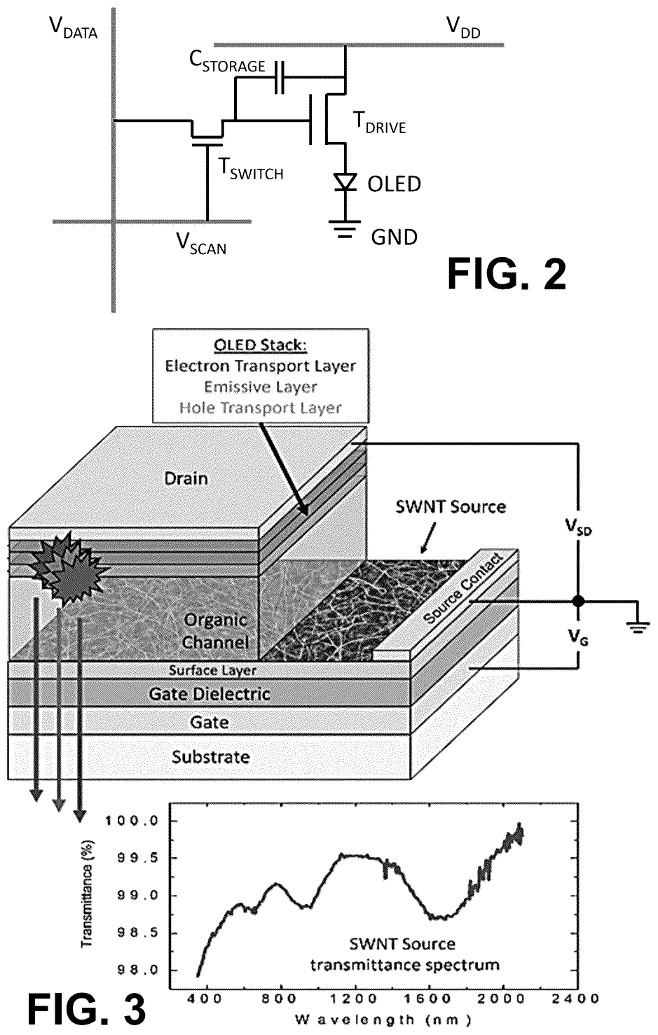

For a conventional thin film transistor (TFT) driven AMOLED, the basic pixel circuit contains a switching transistor (T_{SWITCH}), a driving transistor (T_{DRIVE}), a storage capacitor (C_{STORAGE}) and an OLED. It is called 2T1C circuit because it contains two transistors and one capacitor. Bus lines including the scan line, the data line, the VDD line that provides the power to the OLED, and the ground line. FIG. 2 shows a schematic diagram illustrating a 2T1C pixel circuit. AMOLED panels are current driven emissive displays. To display an image, the transistor backplane sources current to the OLED frontplane where it is converted to visible light in the organic emission material layer (EML). The two basic functions of TFTs in the backplane are to (1) provide stable current to OLED, and (2) to transmit voltage signals that control the current level during each frame time. These two functions are fulfilled by the drive TFT (dr-TFT) and switching TFT (sw-TFT), respectively. The role of the sw-TFT is essentially the same as in an LCD display, working as a switch, transmitting voltage signals from the data line (Vdata signal) that charge a capacitor during the pixel refresh step, and holds that charge on the capacitor which in turn maintains the voltage on the gate of the dr-TFT throughout the refresh cycle. In an LCD display, the Vdata signal controls the LC cell conformation and therefore controls the amount of light that is transmitted from the backlight. In an AMOLED display, the Vdata signal acts on the gate terminal of the dr-TFT which determines the amount of current flowing to the OLED. In both cases, the sw-TFT is acting simply as a voltage switch, and therefore a-Si TFTs like those found in conventional LCD pixels are sufficient.

The performance demands placed on the dr-TFT in an AMOLED pixel are much higher than for the sw-TFTs. To provide sufficient current to drive the OLED pixels requires that the dr-TFT have high-mobility. In order to maintain a steady, consistent pixel brightness, the dr-TFT needs to have good stability without threshold voltage (Vth) shift under all driving conditions. To ensure a uniform display panel without visible mura, the characteristics of the dr-TFTs in all pixels across the panel needs to be consistent. For the conventional lateral channel TFT, most of these requirements rely on the performance of the channel material. At present only LTPS and Oxide TFTs can meet the requirements of the dr-TFTs for AMOLED panels mass produced on large-Gen size substrates. Even for these high performance channel materials manufactured using demanding processes that include elevated temperature, high vacuum, and special treatments, like excimer laser annealing (ELA) for LTPS, non-ideality still exists, and specifically-designed pixel circuits with several additional, in-pixel, TFTs and dedicated drive schemes are needed to compensate for the issues with the dr-TFTs.

The VOLET can overcome many of these issues and provides a solution for AMOLED pixel driving with a novel device architecture. Similar to the bottom gate lateral channel TFT, the VOLET is also a three-terminal device based on the Metal-Oxide-Semiconductor (MOS) structure. FIG. 3 schematically illustrates an example of a VOLET. The core of the VOLET is a dilute CNT network source electrode that geometrically covers the entire gated area of the device while featuring microscopic open areas between conductive elements. Single-walled carbon nanotubes (CNTs), with their long aspect ratios, high electrical conductivity, solution processability, and low density of electronic states, are the material of choice for the network source electrode.

The semiconductor thin film channel material deposited on top of the network source electrode is selected to have a proper carrier injection barrier with the CNTs source electrode. The open regions of the network structure allow for the penetration of the gate field up to the contact interface between the source and the channel semiconductor, modulating the injection barrier between them, which dictates the current flowing through the device. Unlike in a conventional TFT where current flows along the interface between the channel and the gate insulator, laterally across the channel length from the source to the drain, in the VOLET the current flows vertically through the entire cross-section of the channel layer, where the channel length is now defined by the thickness of the semiconductor thin film. FIG. 3 shows the VOLET with an example of a CNT network source electrode transmittance spectrum.

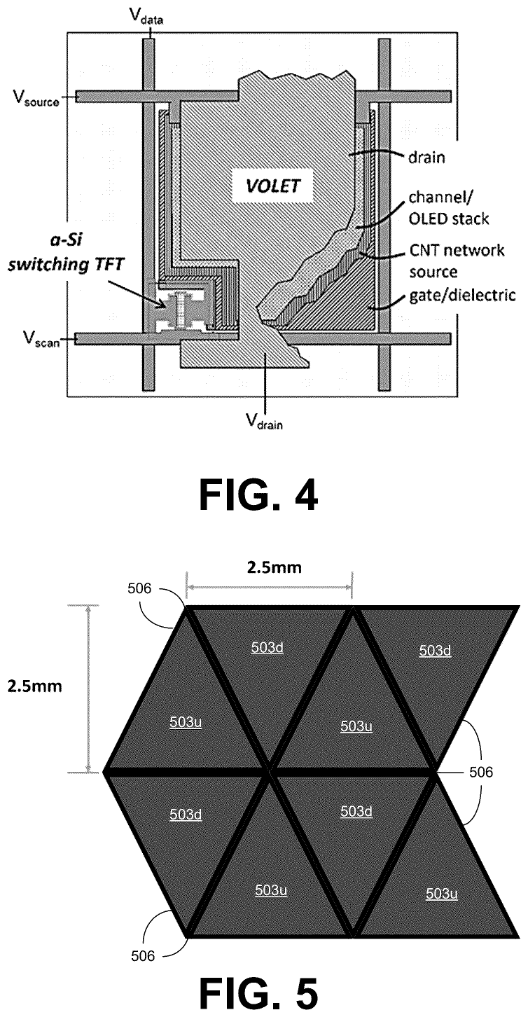

The VOLET brings substantial advantages when it is situated in a bottom emission AMOLED pixel. FIG. 4 shows a schematic of a VOLET and an a-Si switching TFT that simplify the AMOLED display pixel. Since the VOLET emits light across its entire aperture, while simultaneously featuring built-in light emission control as well as intrinsic gate capacitance for charge storage between refresh cycles, the pixel real-estate that would normally accommodate the dr-TFT and the storage capacitor in a conventional AMOLED pixel becomes available for the VOLET, increasing the aperture ratio of the pixel. Along with increased aperture ratio come several benefits to the display. For the same OLED stack, a higher peak panel brightness can be achieved from the increased light-emission proportion. Alternatively, for a comparable pixel brightness, a higher aperture ratio essentially decreases the actual brightness of the light emitting region in the pixel, reducing the emitter's rate of degradation to prolong the display panel lifetime. Furthermore, the high aperture ratio of the VOLET minimizes the screen door effect on the display panel, resulting in a more natural and seamless visual experience.

Aperture ratio, or fill factor, in the context of display screens, refers to the ratio of the active, light-emitting area of each pixel to the total area of that pixel. It is a measure of the proportion of each pixel that is dedicated to producing the image you see on the screen, as opposed to the non-emitting areas such as the gaps between pixels or the area taken up by wiring and other components.

In other words, a higher fill factor means more of each pixel is used for displaying the image, which typically leads to a brighter and more uniformly illuminated screen. High fill factor is desired for a display screen, as the non-emitting areas can become more noticeable and potentially reduce the perceived image quality.

Mathematically, the fill factor can be expressed as a percentage and is calculated by dividing the area of the active region of a pixel by the total area of the pixel, including inactive regions. A fill factor of 100% would mean the entire pixel area contributes to image display, which is the ideal but practically difficult to achieve due to the physical structure of pixels and the need for circuitry within the display.

The intrinsic characteristics of the VOLET based AMOLED, especially high fill factor, makes it the perfect technology for the next generation automobile external display and signaling systems.

Various examples of external display, signaling and lighting devices enabled by the VOLET based AMOLED are now presented. While the examples are discussed in the context of automotive applications, they can be utilized in a wide range of applications including, but not limited to, other vehicles (e.g., ships, boats, aircraft, motorcycles, drones, unmanned vehicles, etc.), signs or displays (e.g., highway signs, construction warnings, advertising, etc.), buildings, or medical displays, including, but no limited to, facial therapy and wound healing treatment applications, or other types of surfaces.

### Active-Matrix VOLET Automotive External Display

The pixel size of this type of display is much larger than that in a typical display screen. In a typical display screen, depending on the screen size and resolution, the pixels are in general on the order of tens to hundreds of microns. The function of the pixels is collectively forming an image that does not depend on the detailed shape of the pixel. In another word, the pixels themselves should be “invisible” and not to be discerned, so the image that is collectively formed by the pixels are clearly and crisply represented, hence Apple's Retina Display, i.e., display screens with a pixel density high enough that the human eye is unable to discern individual pixels at a typical viewing distance.

On the other hand, in the proposed active-matrix VOLET automotive external display, the pixels are much larger, more than one millimeter and typically several millimeters of its length scale in each direction. Therefore, the pixels are discernable by the eyes of a viewer, and the shape and layout of the pixels will play an important role in the visual effects of the display. It is desirable for the automotive external displays to have close to unity fill factor, giving a viewing experience with high level of fullness and richness, and our proposed active-matrix VOLET automotive external display design features high fill factors.

### Example 1 (A)

Referring to FIG. 5, shown is one example of a pixel design of the proposed active-matrix VOLET automotive external display, with triangular pixels. In the example of FIG. 5, the triangular pixels are shown with a pixel length of 2.5 mm, and a height also 2.5 mm. Other combinations of pixel lengths and heights can be utilized based upon the application. Illustrated in FIG. 5 are “monocolor” pixels 503 (e.g., red, green, blue, amber, etc.) lighting up, taking up the majority of the total area, while the black lines 506 represent non-emitting area. There are two types of subpixels, one with the isosceles triangle pointing up (503u), and the other with the isosceles triangle pointing down (503d).

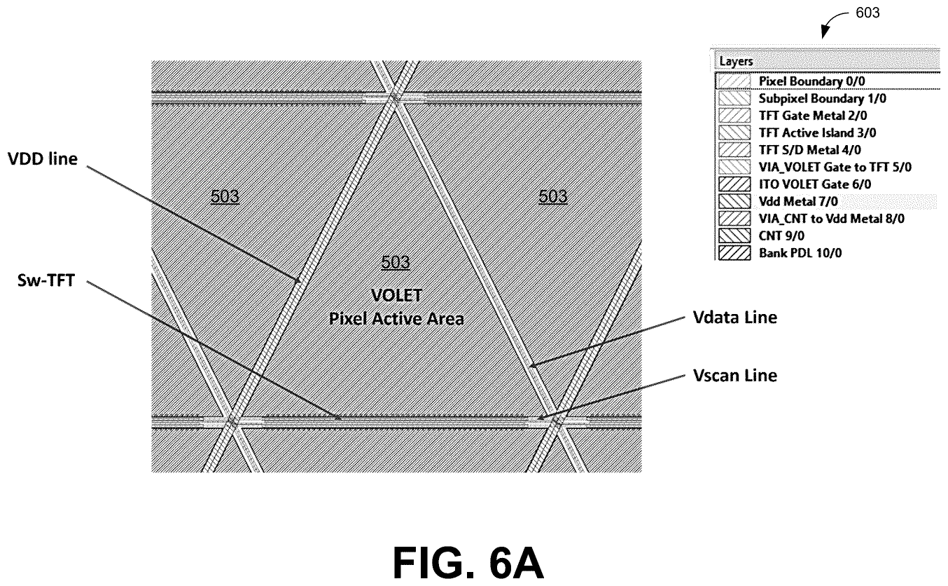

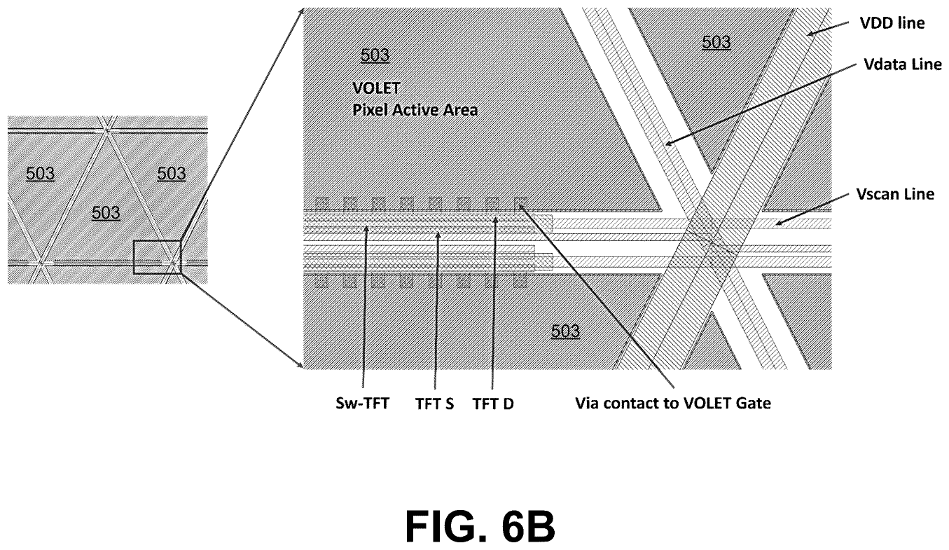

FIGS. 6A and 6B illustrate details of an example of the potential active-matrix VOLET circuit layout for this pixel design. In each pixel, one switching TFT (sw-TFT) is used to address the gate terminal of the VOLET, with the VOLET taking up the majority of the area of the pixel, giving the pixel a large fill factor. In FIG. 6A, the pixel design layout is demonstrated with each functional layer labeled in the inset 603. The bus lines of the display, including the Vdata line, Vscan line and VDD line, are routed along the edges of the pixels 503, each in the direction that follows the shape of the pixel. The Vdata lines are responsible for carrying the image data to the pixels 503, the Vscan line is connected to the gate terminal of a row of TFTs, controlling which row of pixels 503 is being addressed at any given time, and the VDD line supplies the power to the pixels 503. FIG. 6B provides a more detailed look at the pixel circuit, showing one example of the potential routing arrangements for the Vdata line, Vscan line, VDD line. It also provides one example of the potential design of the sw-TFT, which is located along the edge of the pixel 503 at the non-emitting area.

For the pixel design of FIG. 6B, Table 001 below shows the key parameters, as well as the 2*pi*RC switching characteristics and the cutoff frequency with the parameters listed. For an a-Si sw-TFT with a mobility of 0.7 cm²/Vs, a channel width of 2000 μm and channel length of 8 μm, the 2*pi*RC time would be around 66 μs. For a display panel with 80 rows of pixels 503, the required charging time for each row of pixels at a 60 Hz refresh rate is about 208 μs, therefore, such a sw-TFT would be more than sufficient for the switching operation of this panel.

TABLE 001

| Key parameters | H2.28 D 2.28 |
|---|---|
| Pixel W[μm] | 2500.00 |
| Pixel L[μm] | 2500.00 |
| Pixel area [cm²] | 3.13E−02 |
| Aperture Ratio | 0.83 |
| total C [nF] | 5.92E−01 |
| TFT W[μm] | 2000 |
| TFT L[μm] | 8 |
| Mobility[cm²/Vs] | 0.7 |
| TFT R [kohms] | 26.62 |
| 2*pi*RC (μs) | 66.30 |
| cutoff freq (kHz) | 15.08 |

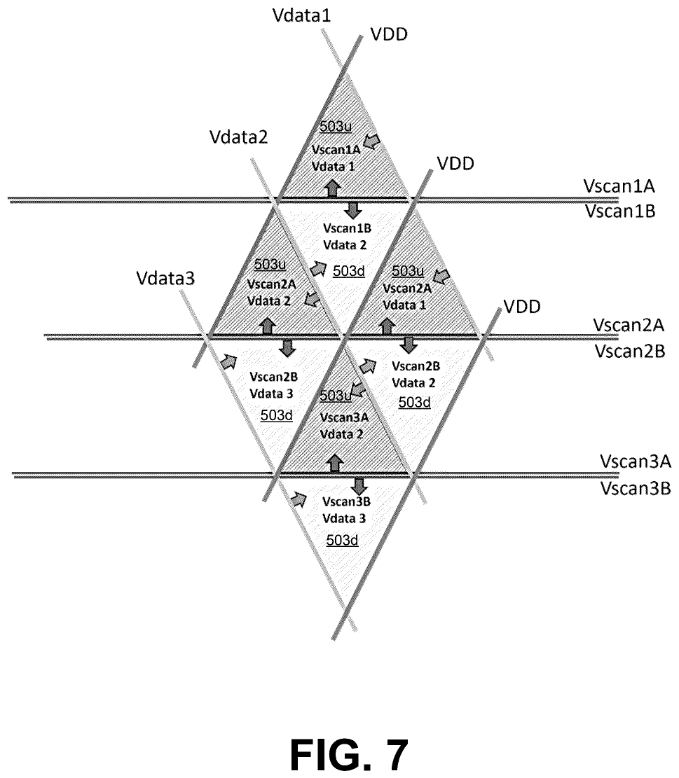

FIG. 7 illustrates an example of the proposed active matrix addressing scheme of a display panel with the full triangle pixels and panel circuit depicted in FIGS. 5, 6A and 6B. For a 100×100 mm display with 2.5 mm pixel pitch, the total subpixel count is 40×80. To drive the pixels 503, one Vdata line is shared between neighboring pixels 503, while two Vscan lines are needed between neighboring rows of pixels 503d and 503u. The effective resolution for driving the display panel is 40×80. And in this case, as stated above, the charging time for each row of pixels at a 60 Hz refresh rate is about 208 μs.

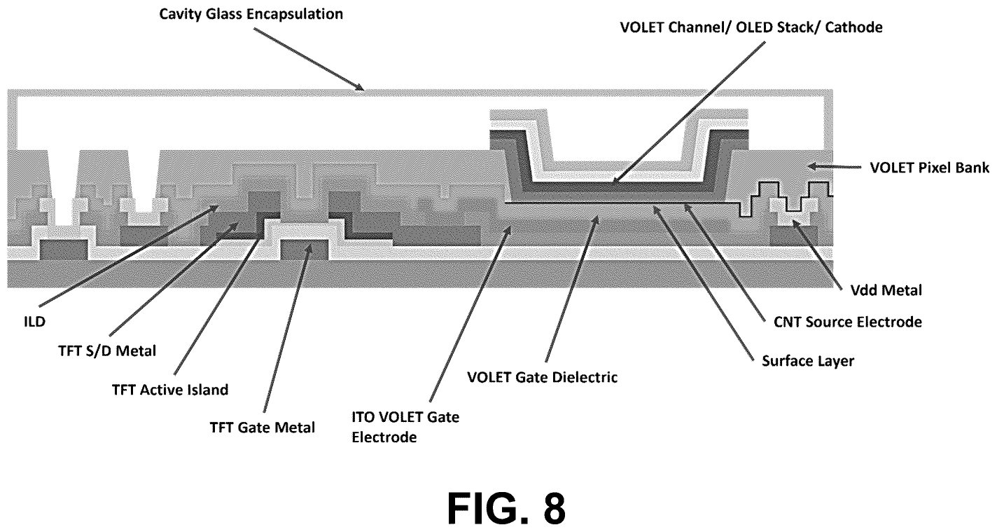

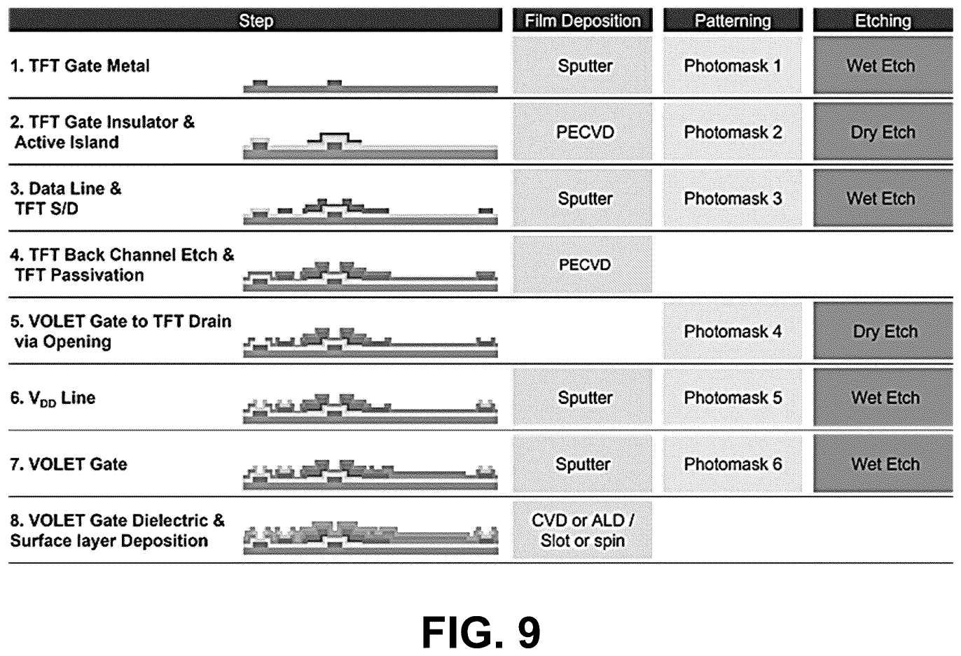

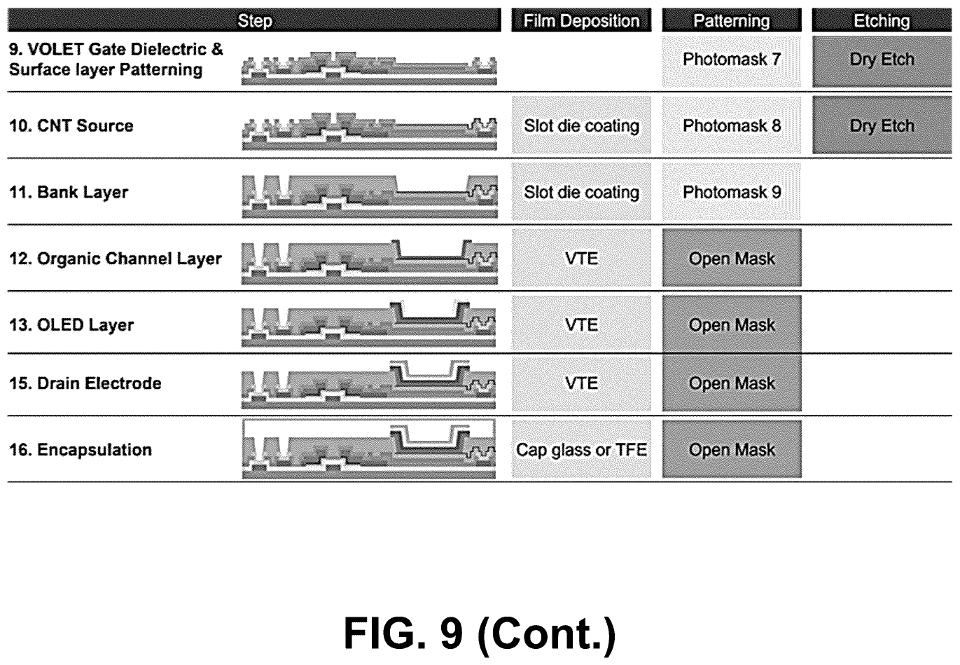

FIG. 8 shows a cross-section view illustrating an example of an active matrix device, and FIG. 9 illustrates an example of a process flow that can be used to fabricate the active matrix device. The process flow includes steps utilizing various combinations of film deposition (using, e.g., sputtering, PECVD, CVD or ALD/slot or spin, slot die coating, VET, and/or cap glass or TFE), patterning (using, e.g., photomasks or open masks) and etching (using, e.g., wet or dry etching) to produce the final device.

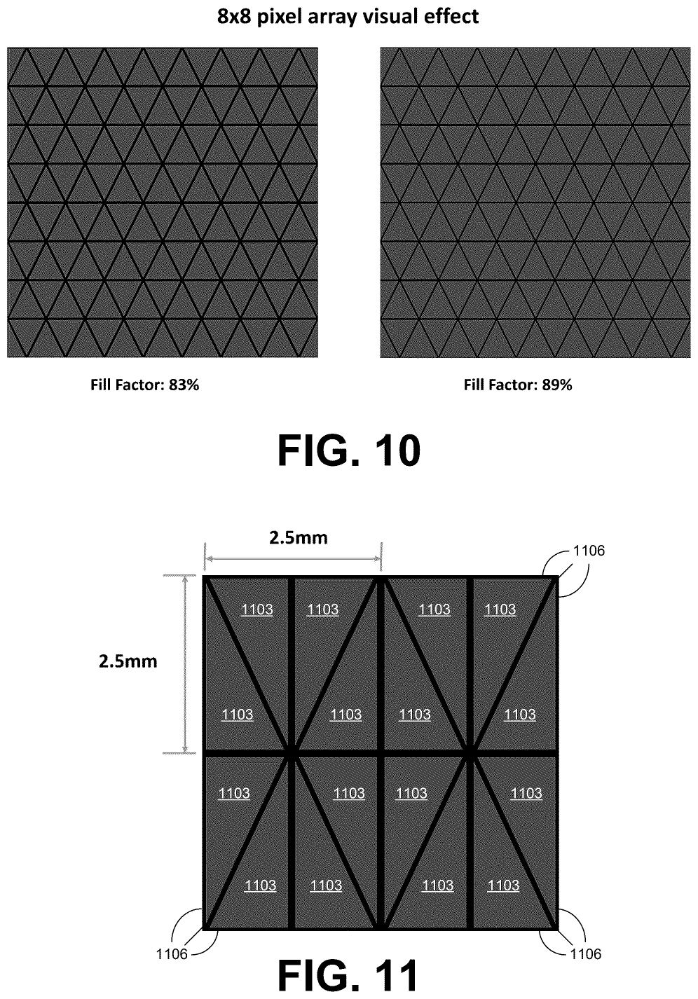

FIG. 10 illustrates an example of the visual effects of an 8×8 pixel array with different fill factors, e.g., 83% and 89%, respectively, with all pixels lighting up. As can be seen, it is desirable to have a higher fill factor in order to enhance the visual effects.

### Example 1 (B)

Referring to FIG. 11, shown is another example of a pixel design of the proposed active-matrix VOLET automotive external display, with split triangular pixels with four subpixels in each unit pixel. In the example of FIG. 11, the pixel has a length of 2.5 mm, and a height also 2.5 mm. Other combinations of pixel lengths and heights can be utilized based upon the application. Shown in FIG. 11 are “monocolor” pixels 1103 (e.g., red, green, blue, amber, etc.) lighting up, taking up the majority of the total area, while the black lines 1106 represent the non-emitting area. The subpixel design features four congruent right triangles with each oriented to together to form a square unit pixel 1103.

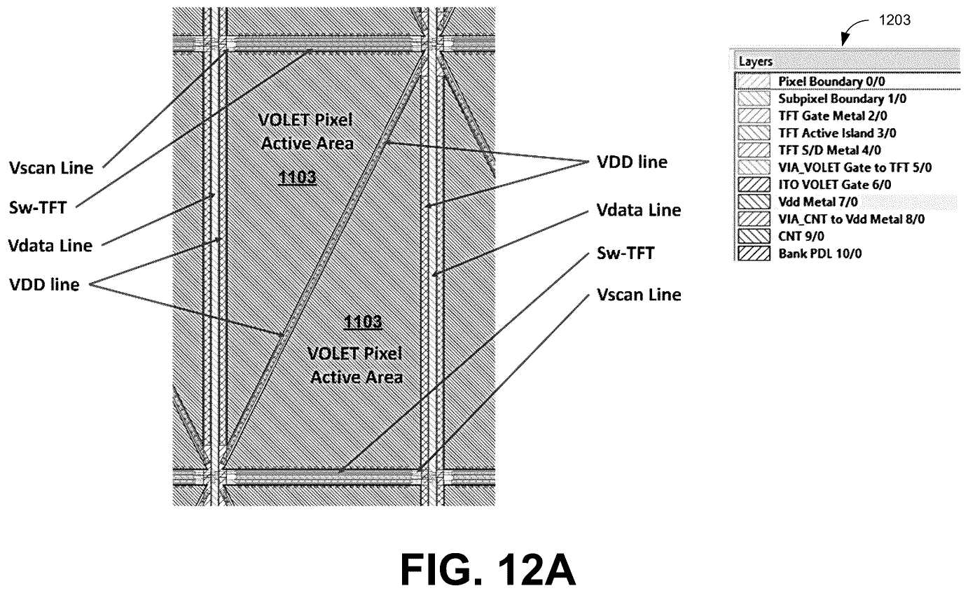

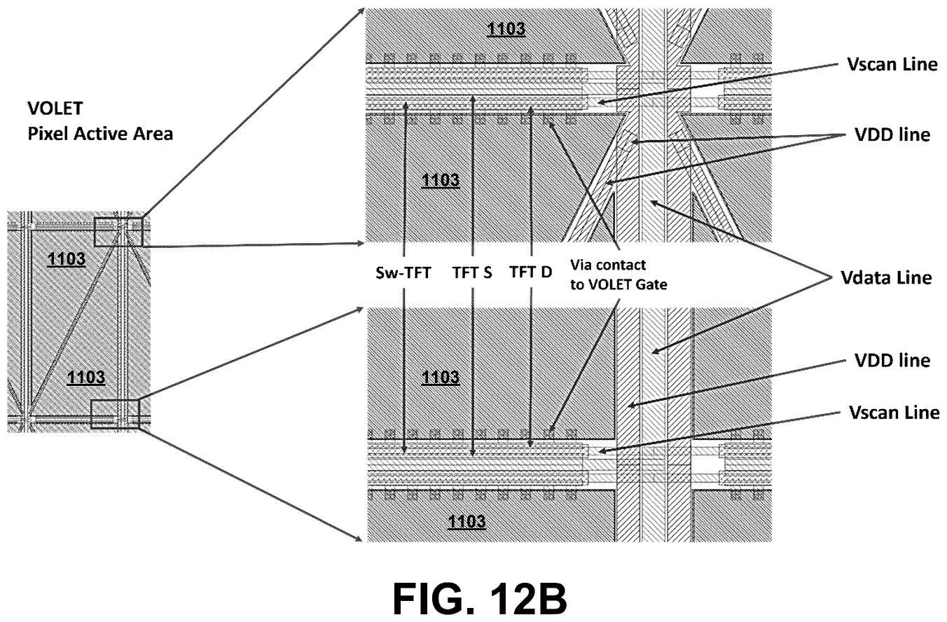

FIGS. 12A and 12B illustrate details of an example of the potential active-matrix VOLET circuit layout for the pixel design of FIG. 11. In each pixel, one switching TFT (Sw-TFT) is used to address the gate terminal of the VOLET, with the VOLET taking the majority area of the pixel 1103 (or subpixel), giving the pixel a large fill factor. In FIG. 12A, the pixel design layout is demonstrated with each functional layer labeled in the inset 1203. The bus lines of the display, including the Vdata line, Vscan line and VDD line, are routed along the edges of the pixels 1103 (or subpixels), each in the direction that follows the shape of the pixel 1103 (or subpixel). FIG. 12B provides a more detailed look at the pixel circuit, showing one example of the potential routing arrangements for the Vdata line, Vscan line, VDD line. It also provides one example of the potential design of the Sw-TFT, which is located along the edge of pixel 1103 (or subpixel) at the non-emitting area.

For the pixel design of FIG. 12B, Table 002 below shows the key parameters, as well as the 2*pi*RC switching characteristics and the cutoff frequency with the parameters listed. For an a-Si sw-TFT with a mobility of 0.7 cm²/Vs, a channel width of 1000 μm and channel length of 8 μm, the 2*pi*RC time would be around 58 μs. For a display panel with 80 rows of pixels, the required charging time for each row of pixels at a 60 Hz refresh rate is about 208 μs, therefore, such a sw-TFT would be more than sufficient for the switching operation of this panel.

TABLE 002

| Key parameters | H2.35 D 1.1 |
|---|---|
| Pixel W[μm] | 1250.00 |
| Pixel L[μm] | 2500.00 |
| Pixel area [cm²] | 1.56E−02 |
| Aperture Ratio | 0.83 |
| total C [nF] | 2.96E−01 |
| TFT W[μm] | 1000 |
| TFT L[μm] | 8 |
| Mobility[cm²/Vs] | 0.7 |
| TFT R [kohms] | 53.25 |
| 2*pi*RC (μs) | 57.92 |
| cutoff freq (kHz) | 17.26 |

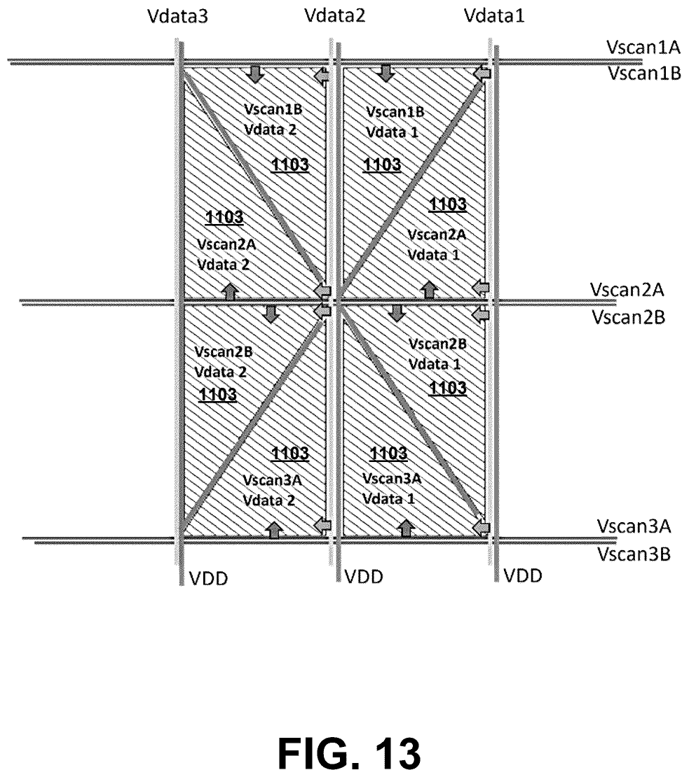

FIG. 13 illustrates an example of the proposed addressing scheme of a display panel with pixel (subpixel) and panel circuit depicted in FIGS. 11, 12A and 12B. For a 100×100 mm display with 2.5 mm pixel pitch 1103, the total subpixel count is 40×160. To drive the pixels 1103, one Vdata line is addressing all subpixels on the same side, while two Vscan lines are needed between neighboring rows of subpixels. The effective resolution for driving the display panel is 80×80. The charging time for each row of pixels at a 60 Hz refresh rate is about 208 μs.

As in example 1 (A), FIG. 8 shows a cross-section illustrating an example of the proposed active matrix device, and FIG. 9 illustrates an example of a process flow that can be used to fabricate the active matrix device.

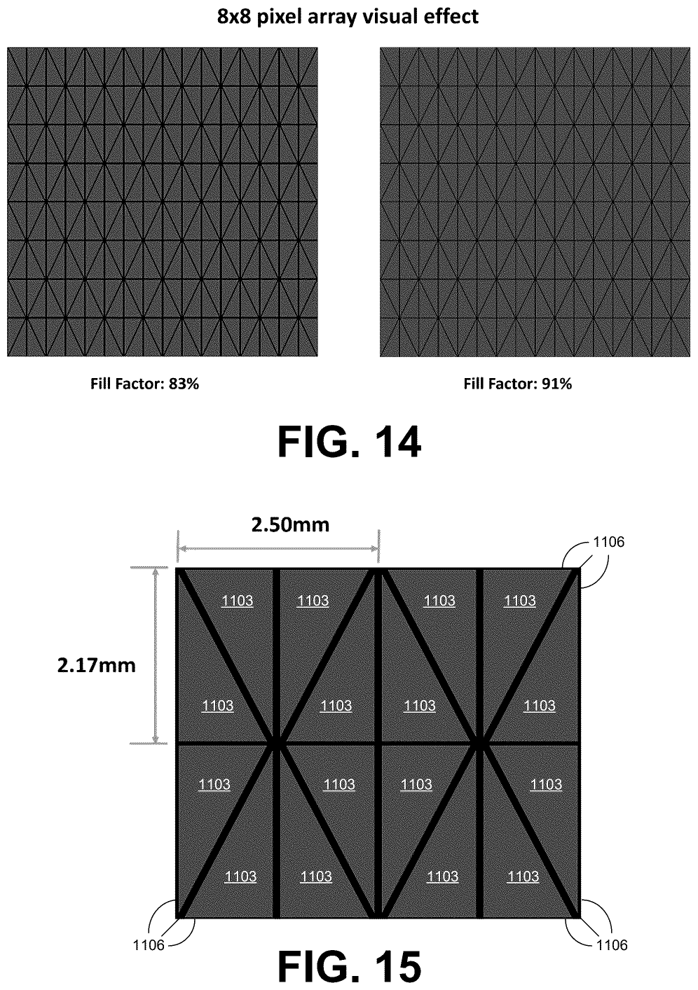

FIG. 14 illustrates an example of the visual effects of an 8×8 pixel array with different fill factors, e.g., 83% and 91%, respectively, with all pixels lighting up. As can be seen, it is desirable to have a higher fill factor in order to enhance the visual effects.

### Example 1 (C)

There can be many variations to pixel design of the VOLET based AMOLED panel for applications such as fitted on the external of an automobile vehicle. Similar to example 1 (B) discussed above, FIG. 15 illustrates another example of a pixel design of the active-matrix VOLET automotive external display, with split triangular pixels with an equilateral triangle shape. Again, there are four subpixels in each unit pixel 1103, and the pixel 1103 has a length of 2.5 mm, and now a height of 2.17 mm. Therefore, in this case, and in general, the aspect ratio of a VOLET based AMOLED display can vary based on the X and Y dimensions of the pixel design. Illustrated in FIG. 15 are “monocolor” pixels 1103 (e.g., red, green, blue, amber, etc.) lighting up, taking up the majority of the total area, while the black lines 1106 represent the non-emitting area. The subpixel design features four congruent right triangles with each oriented to together form a rectangular unit pixel 1103.

An example of the details of a potential active-matrix VOLET circuit layout for this pixel design can be similar to that depicted in FIGS. 12A and 12B. In each pixel 1103, one switching TFT (Sw-TFT) is used to address the gate terminal of the VOLET, with the VOLET taking the majority area of the pixel 1103 (or subpixel), giving the pixel a large fill factor. In FIG. 12A, each functional layer is shown according to the sequence of the fabrication process provided in the inset 1203. The bus lines of the display, including the Vdata line, Vscan line and VDD line, are routed along the edges of the pixels 1103 (or subpixels), each in the direction that follows the shape of the pixel 1103 (or subpixel). FIG. 12B provides a more detailed look at the pixel circuit, showing one example of the potential routing arrangements for the Vdata line, Vscan line, VDD line. It also provides one example of the potential design of the sw-TFT, which is located along the edge of pixel 1103 (or subpixel) at the non-emitting area.

For this pixel design, Table 003 below shows the key parameters, as well as the 2*pi*RC switching characteristics and the cutoff frequency with the parameters listed. For an a-Si sw-TFT with a mobility of 0.7 cm²/Vs, a channel width of 1000 μm and channel length of 8 μm, the 2*pi*RC time would be around 50 μs. This is a shorter time achieved than the case shown in example 1 (B), due to a reduced pixel capacitance from a reduced area as a result of different geometry of the pixel design. For a display panel with 80 rows of pixels, the required charging time for each row of pixels at a 60 Hz refresh rate is about 208 μs, therefore, such a sw-TFT would be more than sufficient for the switching operation of this panel.

TABLE 003

| Key parameters | H2.07 D1.09 |
|---|---|
| Pixel W[μm] | 1250.00 |
| Pixel L[μm] | 2170.00 |
| Pixel area [cm²] | 1.36E−02 |
| Aperture Ratio | 0.83 |
| total C [nF] | 2.57E−01 |
| TFT W[μm] | 1000 |
| TFT L[μm] | 8 |
| Mobility[cm²/Vs] | 0.7 |
| TFT R [kohms] | 53.25 |
| 2*pi*RC (μs) | 50.28 |
| cutoff freq (kHz) | 19.89 |

Similar to the addressing scheme shown in FIG. 13, a display panel with pixel (subpixel) and panel circuit depicted in example 1 (C) can be addressed with such a scheme. For a 100×87 mm display with 2.5 mm pixel pitch, the total subpixel count is 40×160. To drive the pixels 1103, one Vdata line is addressing all subpixels on the same side, while two Vscan lines are needed between neighboring rows of subpixels. The effective resolution for driving the display panel is 80×80. The charging time for each row of pixels at a 60 Hz refresh rate is about 208 μs.

As in examples 1 (A) and 1 (B), FIG. 8 shows a cross-section illustrating an example of the proposed active matrix device, and FIG. 9 illustrates an example of a process flow that can be used to fabricate the active matrix device.

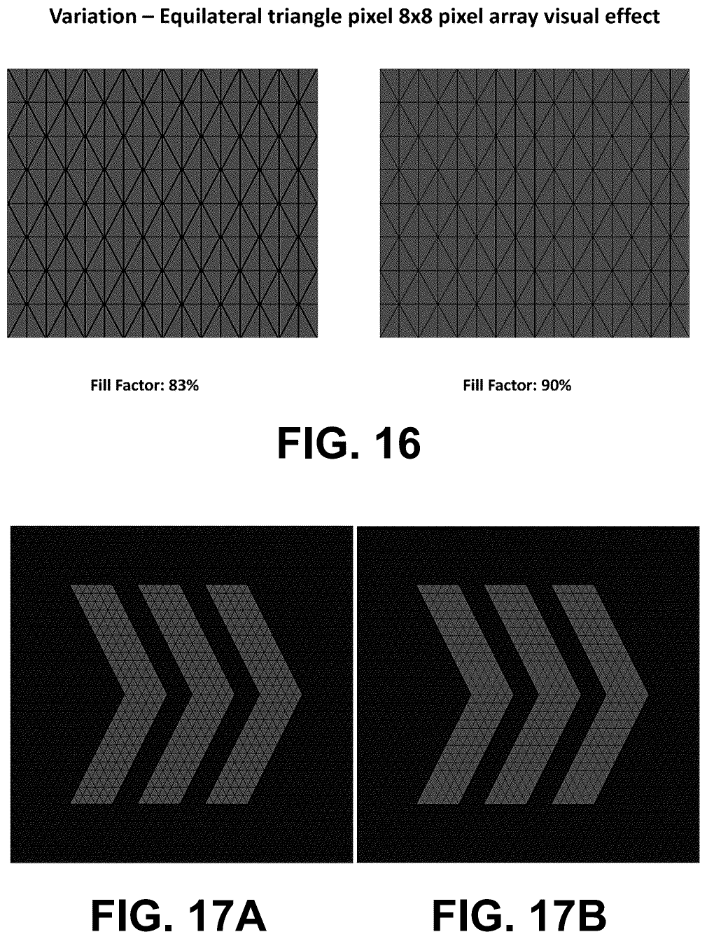

FIG. 16 illustrates an example of the visual effects of an 8×8 pixel array with different fill factors, e.g., 83% and 90%, respectively, with all pixels lighting up. As can be seen, it is desirable to have a higher fill factor in order to enhance the visual effects.

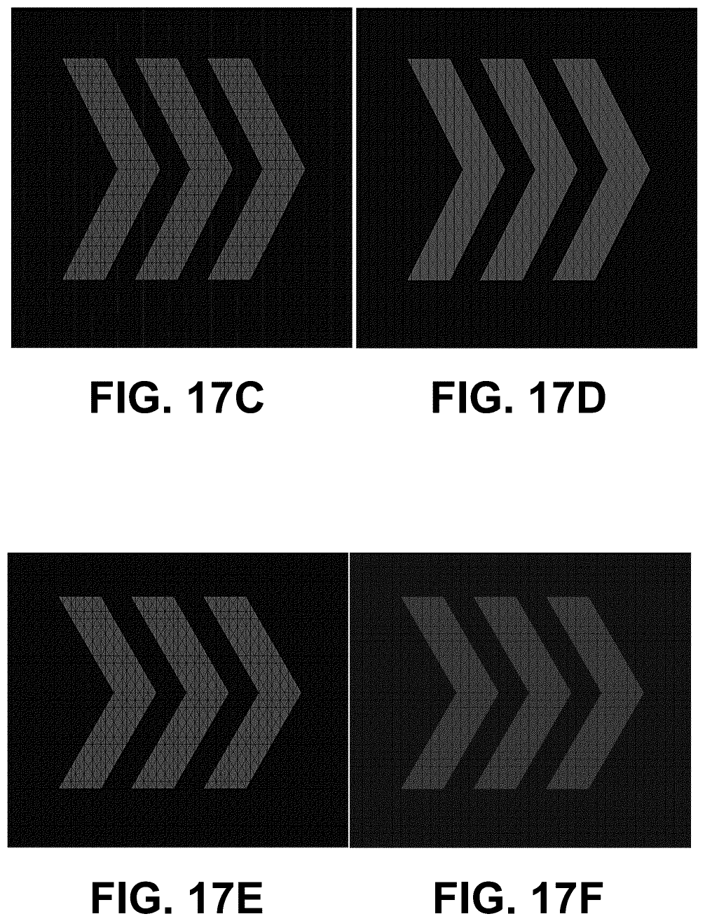

FIGS. 17A-17F illustrate examples of the visual effects of a 40×40 display panel with the pixel layouts discussed in examples 1 (A), 1 (B) and 1 (C), respectively, with different fill factors for each case. The lighted up pixels form a sample pattern, while the other pixels in the panel remain dark at their OFF state. Different pixel designs can provide different visual feelings, and the VOLET pixel enables high fill factors that enhance the visual effects. FIGS. 17A and 17B show full triangle pixel panel visual effects for example 1 (A). In FIG. 17A, the pattern display visual effect is on a 100×100 mm panel with 2.5 mm pixel pitch and a fill factor of 83%. In FIG. 17B, the pattern display visual effect is on a 100×100 mm panel with 2.5 mm pixel pitch and a fill factor of 89%. FIGS. 17C and 17D show split triangle pixel panel visual effects for example 1 (B). In FIG. 17C, the pattern display visual effect is on a 100×100 mm panel with 2.5 mm pixel pitch and a fill factor of 83%. In FIG. 17D, the pattern display visual effect is on a 100×100 mm panel with 2.5 mm pixel pitch and a fill factor of 91%. FIGS. 17E and 17F show split triangle pixel panel visual effects for example 1 (C). In FIG. 17E, the pattern display visual effect is on a 100×87 mm panel with 2.5 mm horizontal pixel pitch and a fill factor of 83%. In FIG. 17F, the pattern display visual effect is on a 100×87 mm panel with 2.5 mm horizontal pixel pitch and a fill factor of 90%.

### Example 1 (D)

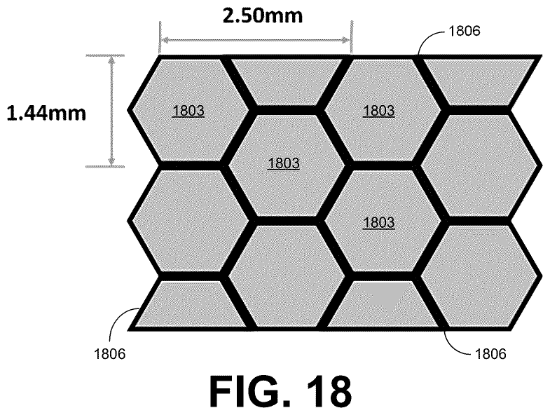

It should be noted that the advantages provided by the VOLET architecture enhance the active-matrix VOLET automotive external display and therefore offer a variety of pixel designs that can suit the need for such applications. FIG. 18 illustrates another example of a pixel design of the active-matrix VOLET automotive external display, with hexagon pixels. In the example of FIG. 18, the pixel design has two subpixels 1803 in each unit pixel. In FIG. 18, the pixel has a pitch with length of 2.5 mm, and a height of 1.44 mm for one hexagon subpixel. Other combinations of pixel lengths and heights can be utilized based upon the application. Shown in FIG. 18 are “monocolor” pixels (e.g., red, green, blue, amber, etc.) lighting up, taking up the majority of the total area, while the black lines 1806 represent non-emitting area. The subpixel design features two congruent hexagons and pixels form a honeycomb pattern. Through this example, it is shown that the color of the pixels can be any color of the choice to fit the needs of the application. Different colors can be achieved by selecting appropriate emitter materials for the OLED stack. It is also possible to build tandem OLED stacks, which means multiple units of light emitting structures stacked on top of each other for various purposes, for example, to offer different colors, to enhance the brightness and reduce the driving current, to achieve a longer lifetime, etc.

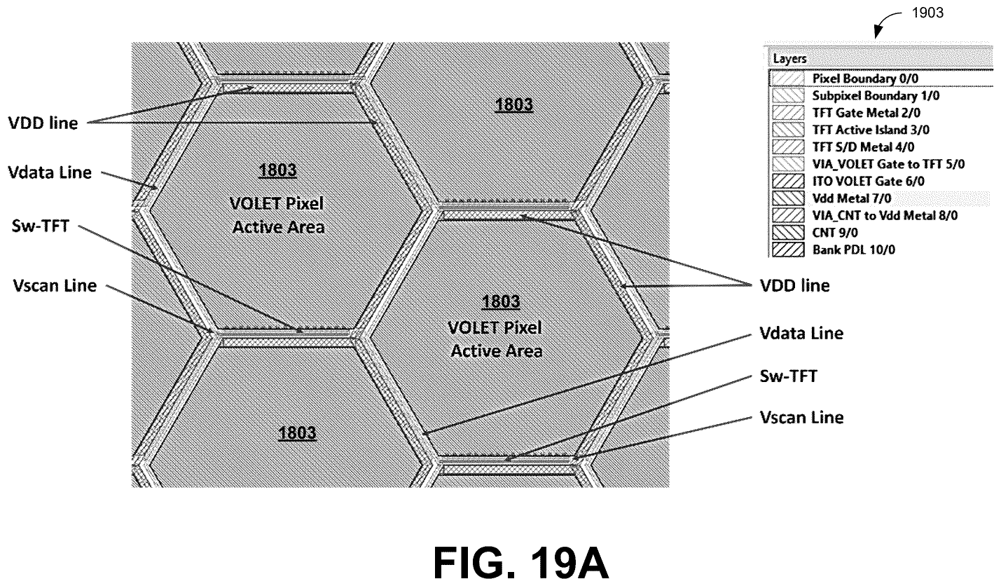

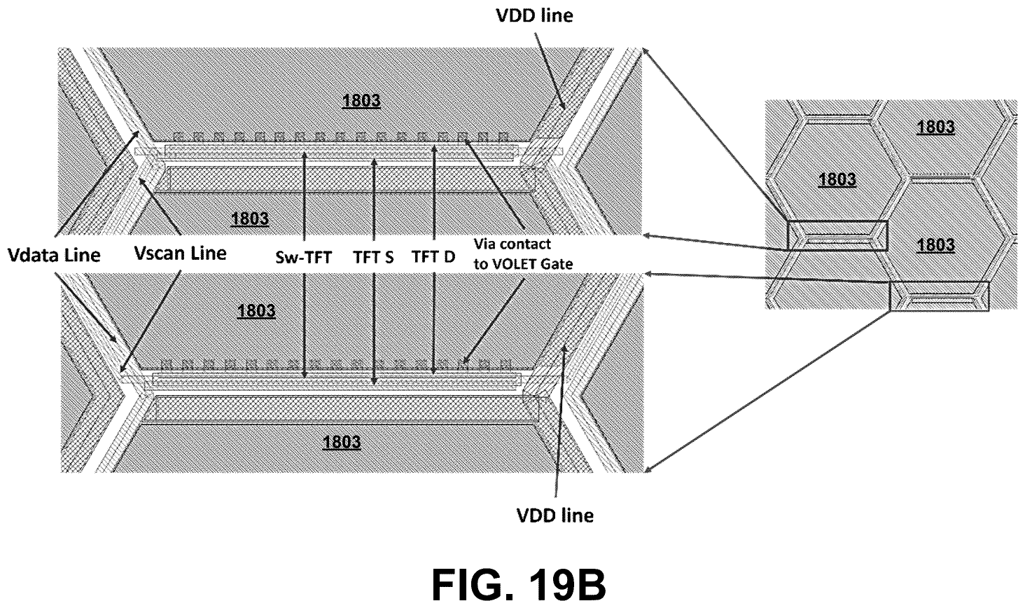

FIGS. 19A and 19B illustrate details of an example of the various potential active-matrix VOLET circuit layouts for the pixel design of FIG. 18. In each pixel, one switching TFT (Sw-TFT) is used to address the gate terminal of the VOLET, with the VOLET taking the majority area of the pixel, giving the pixel a large fill factor. In FIG. 19A, the pixel design layout is demonstrated with each functional layer labeled in the inset 1903. The bus lines of the display, including the Vdata line, Vscan line and VDD line, are routed along the edges of the pixels (or subpixels 1803), each in the direction that follows the shape of the pixel (or subpixel 1803). FIG. 19B provides a more detailed look at the pixel circuit, showing one example of the potential routing arrangements for the Vdata line, Vscan line, VDD line. It also provides one example of the potential design of the sw-TFT, which is located along the edge of pixel (or subpixel 1803) at the non-emitting area.

For the pixel design of FIG. 19B, Table 004 below shows the key parameters, as well as the 2*pi*RC switching characteristics and the cutoff frequency with the parameters listed. For an a-Si sw-TFT with a mobility of 0.7 cm²/Vs, a channel width of 800 μm and channel length of 8 μm, the 2*pi*RC time would be around 81 μs. For a display panel with 40 rows of pixels, the required charging time for each row of pixels at a 60 Hz refresh rate is about 417 μs, therefore, such a sw-TFT would be more than sufficient for the switching operation of this panel.

TABLE 004

| Key parameters | W1.67 H1.44 |
|---|---|
| Pixel W[μm] | 1666 |
| Pixel L[μm] | 1444 |
| Pixel area [cm²] | 1.80E−02 |
| Aperture Ratio | 0.83 |
| total C [nF] | 3.42E−01 |
| TFT W[μm] | 800 |
| TFT L[μm] | 8 |
| Mobility[cm²/Vs] | 0.7 |
| TFT R [kohms] | 66.56 |
| 2*pi*RC (μs) | 81.19 |
| cutoff freq (kHz) | 12.32 |

FIG. 20 illustrates an example of the proposed addressing scheme of a display panel with pixel and panel circuit depicted in FIGS. 18, 19A and 19B. For a 100×58 mm display with 2.5 mm horizontal pixel pitch, the total subpixel count is 40×80. One Vdata line is addressing all pixels on the right side, while one Vscan line is addressing all pixels on the upper side. The effective resolution for driving the display panel is 80×40. The charging time for each row of pixels at a 60 Hz refresh rate is about 417 μs.

As in example 1 (A), FIG. 8 shows a cross-section illustrating an example of the proposed active matrix device, and FIG. 9 illustrates an example of a process flow that can be used to fabricate the active matrix device.

FIG. 21 illustrates an example of the visual effects of an 8×8 pixel array with different fill factors, e.g., 83% and 89%, respectively, with all pixels lighting up. As can be seen, it is desirable to have a higher fill factor in order to enhance the visual effects.

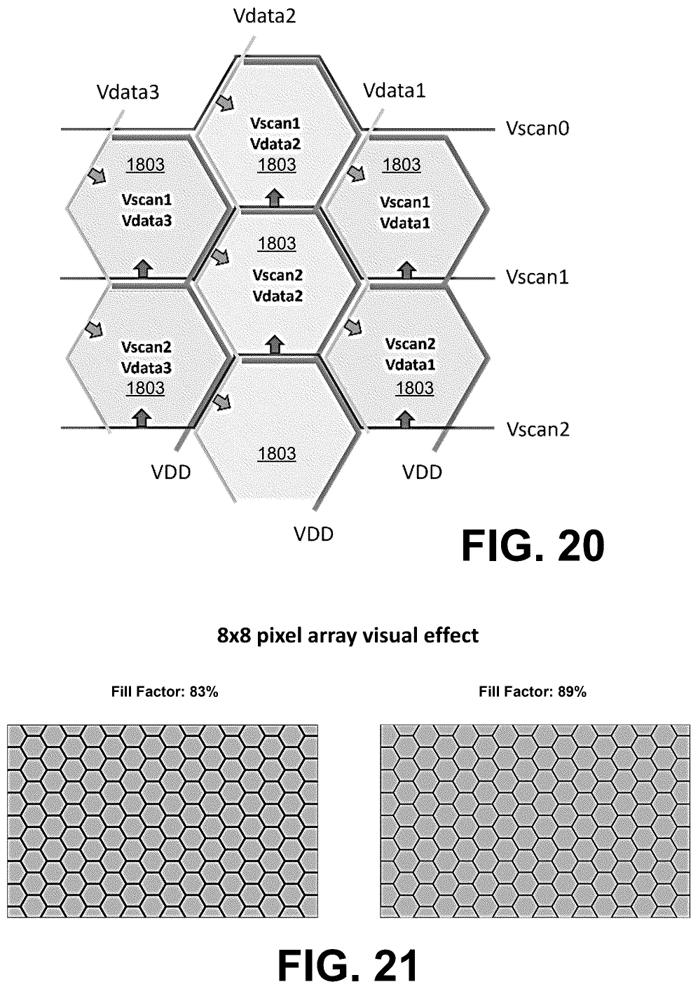

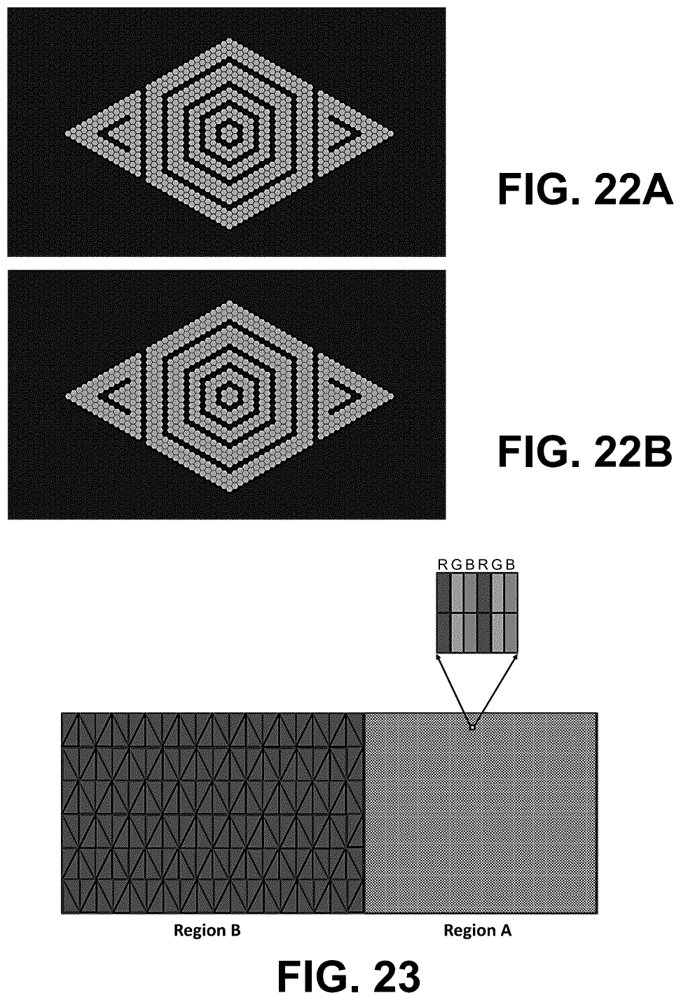

FIGS. 22A and 22B illustrate examples of the visual effects of a 40×40 display panel with the pixel layouts discussed in example 1 (D), with two different fill factors. The lighted up pixels form a sample pattern, while the other pixels in the panel remain dark at their OFF state. Different pixel designs can provide different visual feelings, and the VOLET pixel enables high fill factors that enhance the visual effects. In FIG. 22A, the pattern display visual effect is on a 100×58 mm panel with 2.5 mm horizontal pixel pitch and a fill factor of 83%. In FIG. 22B, the pattern display visual effect is on a 100×58 mm panel with 2.5 mm horizontal pixel pitch and a fill factor of 89%.

Hybrid Active-Matrix VOLET Automotive External Display with Mixed Pixels

As the technology of autonomous vehicles advancing and the needs for vehicle communication evolves, the demand for new solutions changes. A novel solution is proposed by integrating signaling with digital display technologies, enabling the transmission of more sophisticated information through the hybrid device. The proposed solution utilizes the advantages provided by the unique VOLET architecture, which can enable the seamless integration of larger pixels that provide a design feel and aesthetics as previously described, as well as smaller pixels typically found in displays that are individually undiscernible, but collectively form pictures and patterns in a finer detail enabling the delivery of rich information and content.

As can be understood by one of skill in the art, the pixel discernability depends on the viewing distance. For a specific device, the visibly discernable pixels are always larger than the visibly undiscernible pixels. However, when considered across all device types and for various applications, there can be cases when a visibly undiscernible pixel on a device that is meant to be viewed further away would be larger in size than a visibly discernible pixel on a device for close-up viewing. The size of pixels that are visibly undiscernible to a user have a linear dimension in its length, width, height and/or center to center distance in either X or Y axis of 1.5 millimeters (mm) or less, of 1 mm or less, 0.75 mm or less, of 0.5 mm or less, of 0.25 mm or less, or in a range between 1.5 mm and 25 micrometers (μm) or other intermediate ranges as can be appreciated. The size of geometrically shaped, visibly discernable VOLET pixels can have, e.g., a linear dimension in its length, width, height and/or center to center distance in either X or Y axis, of 0.5 mm or greater, of 0.75 mm or greater, of 1 mm or greater, of 1.5 mm or greater, of 2 mm or greater, of 3 mm or greater, of 5 mm or greater, of 10 mm or greater, of 15 mm or greater, or in a range between 0.5 mm and 25 mm, between 1.5 mm and 25 mm, or other intermediate ranges as can be appreciated.

FIG. 23 illustrates another concept of this disclosure. As shown in FIG. 23, the display area can comprise two regions, composed of pixels of different sizes, and capable of serving different functions. In region A, like in a traditional display panel, pixels can be small in size and individually undiscernible by a user, but rather collectively form pictures and patterns to deliver information. In region B, similar to cases previously described with respect to examples 1 (A)-1 (D), the pixels can be much larger and individually visible and discernible, with specifically designed shapes that fulfill the feeling design and luxury, so it is desirable to have a higher fill factor in order to enhance the visual effects. Both regions can be active matrix displays based on a VOLET architecture, with at least one switching TFT in each pixel (or subpixel) addressing the gate terminal of the VOLET.

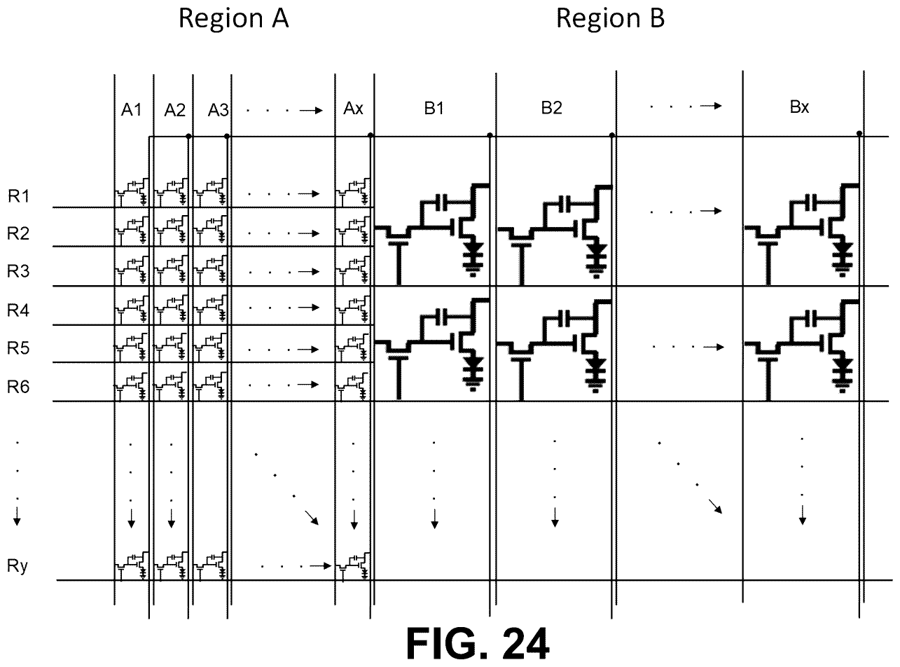

Various design options are available to route the Vgate and Vdata bus lines to achieve active-matrix addressing in both regions of the display area. For example, FIG. 24 shows an example of one scheme where certain Vgate lines are shared between row of pixels in region A and region B.

Both regions can be fabricated through the same process, on the same substrate (e.g., a glass, plastic or any other rigid or flexible substrate), for the backplane process, as well as the VOLET specific process (see, e.g., steps 8, 9, 10 and 11 in FIG. 9). OLED stacks can be separately formed on region A and region B, respectively, to fulfill the color requirements for each region. Typically, the full color of red, green and blue (RGB) pixels are needed for region A, which is a more traditional display screen design, and for region B, a single color (e.g., red or amber color) can be formed to serve the specific needs of showing design patterns formed by the specific shape of larger pixels. Therefore, various techniques to achieve RGB light emission can be employed in region A, including fine metal mask deposition of R, G and B OLED emitters, ink jet printing of R, G and B pixels, white OLED plus color filter, as well as blue OLED plus quantum dot color conversion layers.

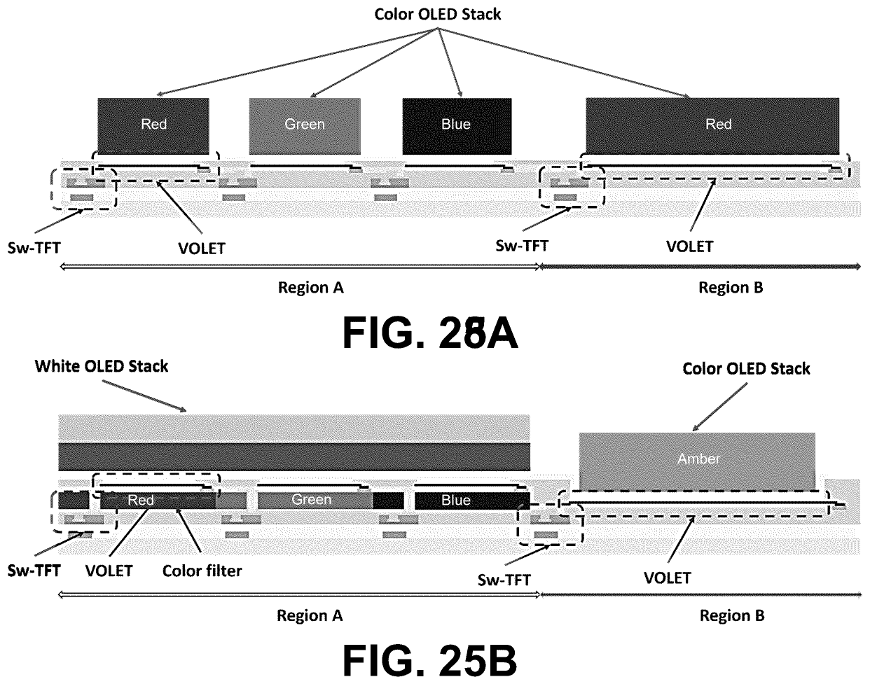

For region B, because the pixels are larger and the shape of pixels is directly visible, it is undesirable to include subpixels of different color because a full and rich light emission of the region, without screen door effect caused by low fill factor of the pixels is typically needed. Therefore, typically only a single color of OLED is formed in region B. However, it is possible to form stack OLEDs with individually controlled emission layers, that could achieve emission color change in region B without losing the fill factor of the region. FIGS. 25A and 25B are cross-sectional views illustrating examples of possible OLED stack formations for a hybrid active-matrix VOLET automotive external display with mixed pixels with colored OLED stacks or a white OLED stack, respectively.

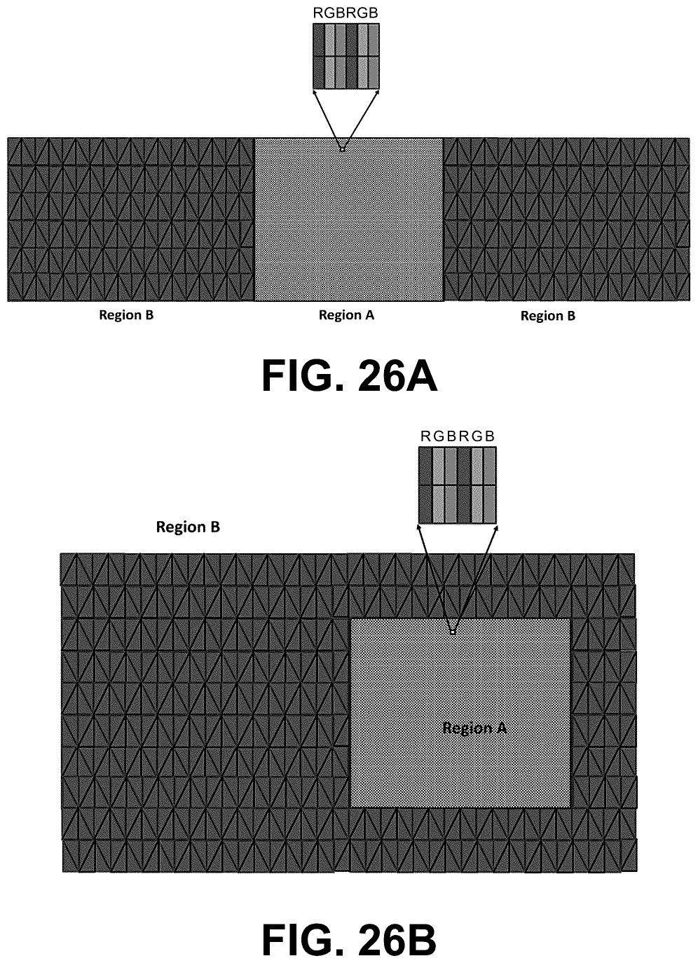

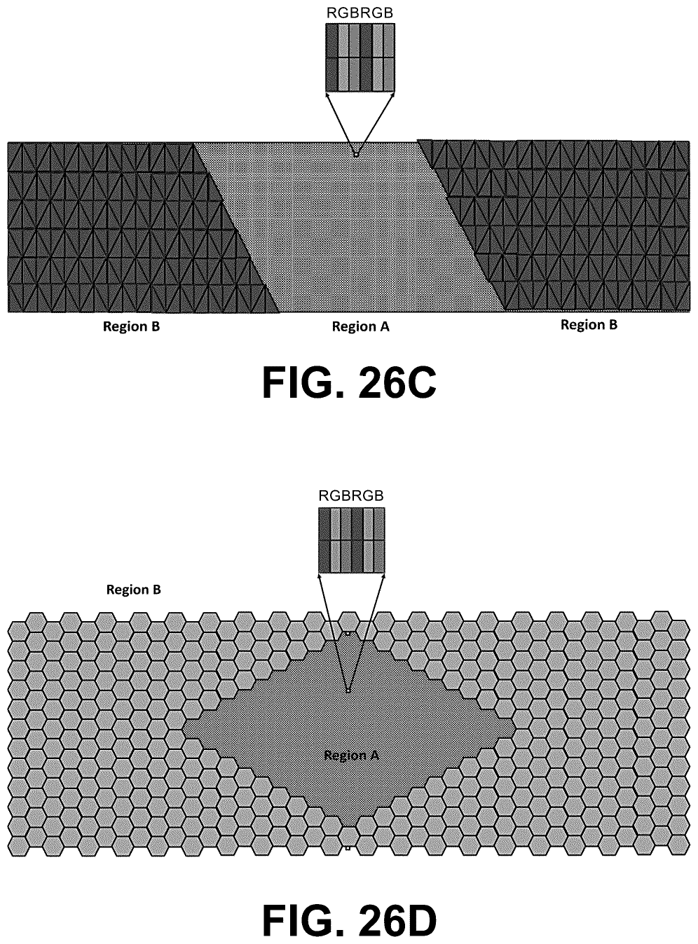

In addition, the pixel regions can be arranged in different configurations other than what is shown in FIG. 23. It is also possible to have more than one region of either region A or region B on the same substrate. It is possible to have different shapes for region A and region B other than rectangular or square as well. FIGS. 26A-26D illustrate examples of a few different possible designs and combinations of region A and region B. FIG. 26A includes a region A with two region Bs on opposite sides. FIG. 26B includes a rectangular region A surrounded by region B. FIG. 26C includes region A with angled sides with two region Bs adjacent to the angled sides. FIG. 26D includes a diamond shaped region A surrounded by region B. Combinations including multiple region As and multiple region Bs are also possible. Other arrangements are possible as can be understood by one of skill in the art.

Monolithic Hybrid Active-Passive-Matrix VOLET/OLED Automotive External Light and Display with Mixed Pixels and Segments

The monolithic hybrid active-passive-matrix VOLET/OLED automotive external light and display can also be expanded with mixed pixels and segments. Based on the previous section, where two regions, region A and region B, of display area with difference pixels are placed, additional regions can be included such as, e.g., region C, where passive matrix VOLET pixels and/or passive matrix OLED pixels situate in the region. The difference is that in region C, there is no switching TFT in each pixel or segment, but rather, pixels or segments are addressed directly by bus lines routes outside of the pixel area. These bus lines can be connected to the gate terminal for a VOLET pixel or segment in region C, or can be connected to the anode or cathode of an OLED pixel or segment in region C. All regions can be fabricated through the same process, on the same substrate (e.g., on a glass, plastic or any other rigid or flexible substrate), for the backplane process.

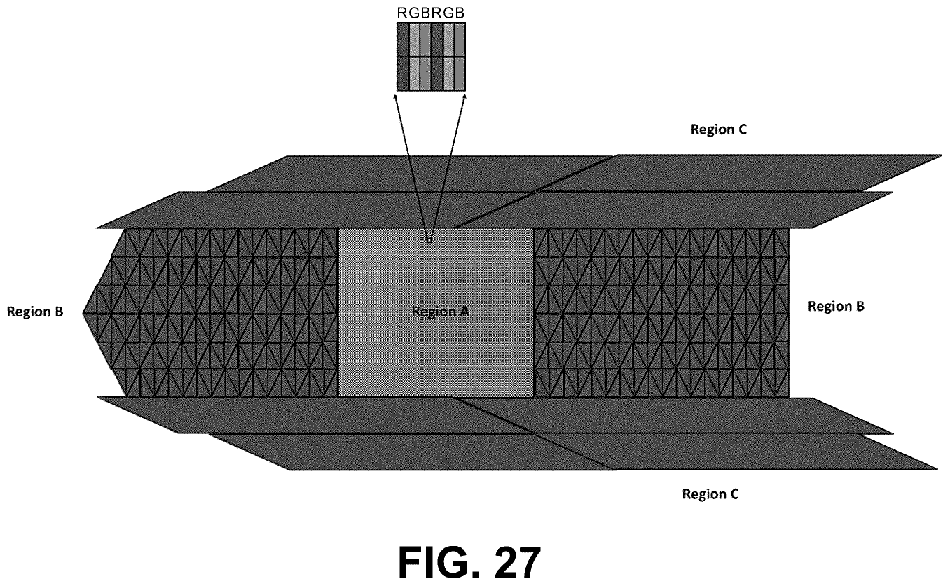

FIG. 27 illustrates an example of another concept of the disclosure. In the example of FIG. 27, there are three regions of the display area, composed of pixels of different sizes, serving different functions. Region A and Region B are similar to the previous descriptions, and there is the 3^{rd} region, region C, that features large segments of passive matrix VOLETs or OLEDs. Both region A and region B are active matrix displays based on VOLET architecture, with at least one switching TFT in each pixel addressing the gate terminal of VOLET, and for segments in region C, there is no switching TFT in each segment. The size of geometrically shaped, visibly discernable VOLET pixels or OLED light emitting segments in region C can have, e.g., a linear dimension in its length, width, height and/or center to center distance in either X or Y axis, of 10 mm or greater, of 15 mm or greater, of 20 mm or greater, of 25 mm or greater, of 50 mm or greater, of 75 mm or greater, of 100 mm or greater, of 200 mm or greater, of 250 mm or greater, or in a range between 10 mm and 500 mm, or other intermediate ranges as can be appreciated.

Various design options are available to route the Vgate and Vdata bus lines to achieve active-matrix addressing in both region A and region B of the display area, and the power supply line for VOLET or OLED segments in region C can also take various routing design.

All regions can be fabricated through the same process, on the same substrate (e.g., a glass, plastic or any other rigid or flexible substrate), for the backplane process. If a VOLET is used in region C, then all regions can also be processed through the VOLET specific process (see, e.g., steps 8, 9, 10 and 11 in FIG. 9). If OLED is used in region C, then this region can be designed to be compatible with the VOLET specific process, but without leaving any lithography feature from the VOLET specific process (see, e.g., steps 8, 9, 10 and 11 in FIG. 9). In this case, step 7 in FIG. 9, which patterns the ITO layer that serves as the gate of the VOLET in other regions, would be serving as the pixel electrode, such as the anode, for the OLED of each segment in this region C. The OLED stacks can be separately formed on region A, region B, and region C, respectively, to fulfill the color requirements for each region. Typically, the full color of RBG pixels are needed for region A which is a more traditional display screen design, and for region B and C a single color (e.g., red or amber color) is formed to serve the specific needs of showing design patterns formed by the specific shape of larger pixels. Therefore, various techniques to achieve red, green and blue light emission can be employed in region A, including fine metal mask deposition of R, G and B OLED emitters, ink jet printing of R, G and B pixels, white OLED plus color filter, as well as blue OLED plus quantum dot color conversion layers.

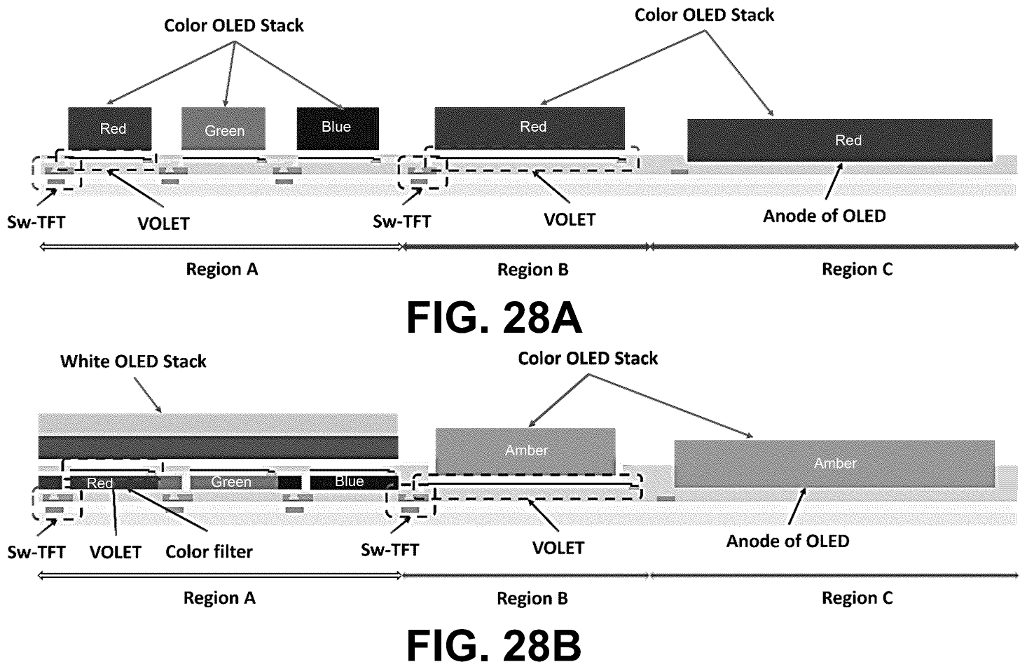

For region B and C, because the pixels are larger and shape of pixels directly visible, it is undesirable to include subpixels of different color because a uniform light emission of the region is typically needed. Therefore, typically only a single color of OLED is formed in regions B and C. However, it is possible to form stack OLEDs with individually controlled emission layers, that can achieve emission color change in region B and C without losing fill factor of the region. FIGS. 28A and 28B are cross-sectional views illustrating examples of possible OLED stack formations for a monolithic hybrid active-passive-matrix VOLET/OLED automotive external light and display with mixed pixels and segments with colored OLED stacks or a white OLED stack, respectively.

An active-matrix automotive external display has been proposed that is enabled by the VOLET which can help to achieve high fill factor, giving the external display a feeling of luxury and help achieve rich design concepts. Different from typical display panels, where individual pixels are indistinguishable, in the proposed display, the pixels are larger, with their shape dedicatedly designed to be visible and discernable, and collectively form patterns that are needed for the vehicle to display patterns, shapes, symbols, letters, words, sentences, characters, and other meaningful visual cues for applications such as signaling the vehicle's intension, providing guidance for other vehicles and/or pedestrians, show casing the vehicle's style and design features, as well as displaying commercials and advertisements. A switching TFT is incorporated in each pixel to achieve active-matrix addressing.

Expanding on this concept, a hybrid active-matrix VOLET automotive external display with mixed pixels, and a monolithic hybrid active-passive-matrix VOLET/OLED automotive external light and display with mixed pixels and segments, are further proposed. In both type of devices, there are regions in the display that features traditional display pixels that are active-matrix addressed and indistinguishable, as well as larger segments that are passive-matrix addressed or directly driven by bus lines. In all cases, the device can be fabricated through the same process, on the same substrate (e.g., a glass, plastic or any other rigid or flexible substrate), for the backplane process, as well as the VOLET specific layers' process. OLED or other light emission layers such as, e.g., quantum dot LED (QD-LED) can be formed during the same process, or in separate process runs for different regions.

While this disclosure is presented in the context of automotive external displays, it can be utilized in a wide range of applications including other vehicles (e.g., ships, boats, aircraft, motorcycles, drones, unmanned vehicles, etc.), signs or displays (e.g., highway signs, construction warnings, advertising, etc.), building, or medical displays, including, but no limited to, facial therapy and wound healing treatment applications, or other types of surfaces.

It should be emphasized that the above-described embodiments of the present disclosure are merely possible examples of implementations set forth for a clear understanding of the principles of the disclosure. Many variations and modifications may be made to the above-described embodiment(s) without departing substantially from the spirit and principles of the disclosure. All such modifications and variations are intended to be included herein within the scope of this disclosure and protected by the following claims.

The term “substantially” is meant to permit deviations from the descriptive term that don't negatively impact the intended purpose. Descriptive terms are implicitly understood to be modified by the word substantially, even if the term is not explicitly modified by the word substantially.

It should be noted that ratios, concentrations, amounts, and other numerical data may be expressed herein in a range format. It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a concentration range of “about 0.1% to about 5%” should be interpreted to include not only the explicitly recited concentration of about 0.1 wt % to about 5 wt %, but also include individual concentrations (e.g., 1%, 2%, 3%, and 4%) and the sub-ranges (e.g., 0.5%, 1.1%, 2.2%, 3.3%, and 4.4%) within the indicated range. The term “about” can include traditional rounding according to significant figures of numerical values. In addition, the phrase “about ‘x’ to ‘y’” includes “about ‘x’ to about ‘y’”.

1. An active matrix device, comprising:
an array of geometrically shaped VOLET pixels arranged to form an emissive display, where each pixel is visibly discernable to a user; and
bus lines comprising a Vdata line, a Vscan line, and a VDD line routed along edges of the geometrically shaped VOLET pixels.

2. The active matrix device of claim 1, wherein the geometrically shaped VOLET pixels comprise triangular pixels.

3. The active matrix device of claim 2, wherein the Vdata line, Vscan line, and VDD line are routed along different edges of the triangular pixels.

4. The active matrix device of claim 1, wherein the geometrically shaped VOLET pixels have a linear dimension in its length, width, height or center to center distance in either X or Y axis in a range between 0.5 millimeters and 25 millimeters.

5. The active matrix device of claim 1, comprising:
a first region formed by the array of geometrically shaped VOLET pixels; and
a second region comprising a display panel including pixels that are visibly undiscernible to the user.

6. The active matrix device of claim 5, wherein the first and second regions share a portion of the bus lines.

7. The active matrix device of claim 5, wherein both the first region and the second region are fabricated on a common substrate through a series of common processing steps.

8. The active matrix device of claim 7, wherein the substrate is flexible.

9. The active matrix device of claim 8, wherein the substrate comprises a polyimide material.

10. The active matrix device of claim 5, wherein:
the pixels in the second region that are visibly undiscernible to the user have a linear dimension in its length, width, height or center to center distance in either X or Y axis in a range between 25 micrometers and 1.5 millimeters; and
the geometrically shaped VOLET pixels have a linear dimension in its length, width, height or center to center distance in either X or Y axis greater than 1.5 millimeters.

11. The active matrix device of claim 5, wherein individual pixels in the second region that are visibly undiscernible to the user comprise two or more individually controllable sub-pixels with different color emission thereby allowing each pixel to represent a plurality of colors perceivable by human.

12. The active matrix device of claim 5, comprising a third region comprising one or more passively addressed or individual bus line direct driven VOLET pixels or OLED light emitting segments that are larger than the geometrically shaped VOLET pixels.

13. The active matrix device of claim 12, wherein the first region, the second region, and the third region are fabricated on a common substrate through a series of common processing steps.

14. The active matrix device of claim 13, wherein the substrate is flexible.

15. The active matrix device of claim 14, wherein the substrate comprises a polyimide material.

16. The active matrix device of claim 12, wherein the one or more passively addressed or individual bus line direct driven VOLET pixels or OLED light emitting segments in the third region have a linear dimension in its length, width, height and/or center to center distance in either X or Y axis in a range between 10 millimeters and 500 millimeters.

17. The active matrix device of claim 1, wherein each geometrically shaped VOLET pixel comprises a switching thin film transistor (sw-TFT) disposed along an edge of that geometrically shaped VOLET pixel.

18. The active matrix device of claim 17, wherein the sw-TFT is at least partially disposed below a non-emitting area of the geometrically shaped VOLET pixel.

19. The active matrix device of claim 1, wherein the bus lines are routed along non-emitting areas between the geometrically shaped VOLET pixels.

20. The active matrix device of claim 19, wherein the Vdata line is routed along a first side of a geometrically shaped VOLET pixel, the Vscan line is routed along a second side of the geometrically shaped VOLET pixel, and the VDD line is routed along a third side of the geometrically shaped VOLET pixel.

21. The active matrix device of claim 1, wherein the bus lines comprise first and second Vscan lines routed in parallel, positioned side-by-side along edges of adjacent geometrically shaped VOLET pixels.

22. The active matrix device of claim 21, wherein the first Vscan line is coupled to geometrically shaped VOLET pixels on a first side of the first and second Vscan lines and the second Vscan line is coupled to geometrically shaped VOLET pixels on a second side of the first and second Vscan lines.

23. The active matrix device of claim 22, wherein the Vdata line is routed along edges of adjacent geometrically shaped VOLET pixels, and coupled to the adjacent geometrically shaped VOLET pixels, which are coupled by different Vscan lines, on both a first side and a second side of the Vdata line.

24. The active matrix device of claim 1, wherein the geometrically shaped VOLET pixels have a fill factor of greater than 80%, or greater than 87%, or greater than 90%.

25. The active matrix device of claim 1, wherein each of the geometrically shaped VOLET pixels are separated into a plurality of subpixels.

26. The active matrix device of claim 25, wherein the plurality of subpixels comprise triangular subpixels.

27. The active matrix device of claim 25, wherein the plurality of subpixels comprise hexagonal subpixels.

28. The active matrix device of claim 25, wherein each subpixel comprises a switching thin film transistor (sw-TFT) disposed along an edge of that subpixel.

29. The active matrix device of claim 28, wherein the sw-TFT is at least partially disposed below a non-emitting area of the subpixel.
